(19) United States
(12) Patent Application Publication
(10) Pub. No.: US 2019/0093225 A1
(43) Pub. Date: Mar. 28, 2019

(54) PLASMA DEPOSITION METHOD

(71) Applicant: SEMBLANT LIMITED, London (GB)

(72) Inventors: Shailendra Vikram SINGH, Melbourn, Hertfordshire (GB); Richard Anthony LIONE, Melbourn, Hertfordshire (GB)

(21) Appl. No.: 16/082,740

(22) PCT Filed: Mar. 6, 2017
(86) PCT No.: PCT/GB2017/050590

§ 371 Date: Sep. 6, 2018

(30) Foreign Application Priority Data
Mar. 8, 2016 (GB) 1603988.5

(51) Int. Cl. C23C 16/503; C23C 16/02; C23C 16/56; C23C 16/44; C23C 16/511; B05D 1/00; B05D 3/00

(52) U.S. Cl. CPC C23C 16/503; C23C 16/0272; C23C 16/56; C23C 16/4407; B05D 2259/00; C23C 16/511; B05D 1/62; B05D 3/002; C23C 16/4404

(57) ABSTRACT

A plasma deposition method in which a cover layer is deposited onto the internal walls of an empty plasma chamber by plasma deposition of a precursor mixture comprising (i) one or more hydrocarbon compounds of formula (A), or (ii) one or more C₁-C₃ alkane, C₂-C₃ alkene or C₂-C₃ alkyne compounds: (Formula (A)) wherein: Z₁ represents C₁-C₃ alkyl or C₂-C₃ alkenyl; Z₂ represents hydrogen, C₁-C₃ alkyl or C₂-C₃ alkenyl; Z₃ represents hydrogen, C₁-C₃ alkyl or C₂-C₃ alkenyl; Z₄ represents hydrogen, C₁-C₃ alkyl or C₂-C₃ alkenyl; Z₅ represents hydrogen, C₁-C₃ alkyl or C₂-C₃ alkenyl; and Z₆ represents hydrogen, C₁-C₃ alkyl or C₂-C₃ alkenyl.

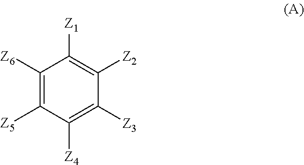

### FIELD OF THE INVENTION

The present invention relates to a method for preparing a cover layer for the internal walls of plasma chambers, to subsequent deposition of conformal coatings onto electrical assemblies using plasma chambers with this cover layer, and to subsequent removal of the cover layer and materials deposited thereon during formation of the conformal coating.

### BACKGROUND TO THE INVENTION

Conformal coatings have been used for many years in the electronics industry to protect electrical assemblies from environmental exposure during operation. A conformal coating is a thin and flexible layer of protective lacquer that conforms to the contours of an electrical assembly, such as a printed circuit board, and its components. Plasma deposited coatings have emerged as promising alternatives to conventional conformal coatings, and have been described in, for example, WO 2013/132250.

The plasma deposition process involves placing the electrical assembly onto which the conformal coating is to be deposited into a plasma chamber, following which the plasma deposition process is conducted such that the conformal coating is deposited on the electrical assembly. However, the plasma deposition process does not generally deposit the coating only onto the electrical assembly. Normally, at least some of the coating is deposited also onto the internal walls of the plasma chamber and onto any other surfaces exposed to the process.

As a result, when repeated cycles of deposition are carried out on multiple electrical assemblies, there is undesirable build-up of material on the internal walls of the plasma chamber which it is necessary to remove periodically. If the material deposited on the internal walls is not removed, it may interfere electrically, physically and/or chemically with the plasma deposition process. Portions of the materials deposited on the internal walls may also start to fall off and onto the electrical assembly being coated. The materials deposited on the internal walls of the plasma chamber thus reduce the quality of the conformal coatings deposited onto the electrical assembly. The overall efficiency of the plasma deposition process may also be adversely affected.

Removal of the material deposited on the internal walls of the plasma chamber can be challenging. Many of the materials deposited during plasma deposition processes, such as those described in WO 2013/132250, have very high levels of adhesion to the internal walls of plasma chambers, and in particular to the metallic portions of those walls.

As a result, it is often difficult, or in some cases impossible, to remove fully the material deposited on the internal walls of the plasma chamber. For example, plasma cleaning or etching can be used to clean the chamber, but requires almost the same, or sometimes more, time to remove material deposited on the internal walls as required to deposit it in the first place. This adversely affects the throughput and power consumption of the overall process.

Sheets of metal or polymers such as polyesters have been used to physically cover the internal walls of the plasma chamber. However, these sheets needs to be manufactured especially for each plasma chamber and it is time consuming to introduce and remove them from the plasma chamber. Further, the presence of the sheets in the plasma chamber means that there is a longer pumping down time during the plasma deposition process, and thus the efficiency of the process is reduced.

There therefore exists a need for improved and more efficient methods for removing the materials deposited on the internal walls of plasma chambers during deposition processes.

### SUMMARY OF THE INVENTION

The present inventors have surprisingly found that it is possible to remove easily the materials deposited on the internal walls of plasma chambers during deposition processes by initially depositing a cover layer on the internal walls of the plasma chambers. The cover layer is deposited prior to introducing the electrical assembly onto which a coating is to be deposited into the plasma chamber. When conformal coatings are subsequently deposited onto electrical assemblies introduced into the plasma chamber, materials are also deposited directly onto the cover layer. The cover layer can subsequently be conveniently removed, together with any materials deposited on it, leaving a clean plasma chamber. The presence of the cover layer does not increase the pumping down time in the plasma deposition process, and thus the efficiency of the process is not reduced by the presence of the cover layer.

Accordingly, the present invention provides plasma deposition method in which a cover layer is deposited onto the internal walls of an empty plasma chamber by plasma deposition of a precursor mixture comprising (i) one or more hydrocarbon compounds of formula (A), or (ii) one or more C₁-C₃ alkane, C₂-C₃ alkene or C₂-C₃ alkyne compounds:

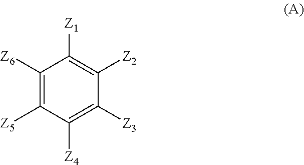

wherein:

Z₁ represents C₁-C₃ alkyl or C₂-C₃ alkenyl;

Z₂ represents hydrogen, C₁-C₃ alkyl or C₂-C₃ alkenyl;

Z₃ represents hydrogen, C₁-C₃ alkyl or C₂-C₃ alkenyl;

Z₄ represents hydrogen, C₁-C₃ alkyl or C₂-C₃ alkenyl;

Z₅ represents hydrogen, C₁-C₃ alkyl or C₂-C₃ alkenyl; and

Z₆ represents hydrogen, C₁-C₃ alkyl or C₂-C₃ alkenyl.

### BRIEF DESCRIPTION OF THE FIGURES

FIG. 1 shows an empty plasma chamber prior to addition of the cover layer of the present invention.

FIG. 2 shows an empty plasma chamber to which the cover layer of the invention has been added by plasma deposition.

FIG. 3 shows a plasma chamber containing an electrical assembly to which a conformal coating has been applied, and which has material deposited on the cover layer.

### DETAILED DESCRIPTION OF THE INVENTION

### Plasma Deposition Methods

The present invention is concerned with plasma deposition methods, which are typically plasma enhanced chemical vapour deposition (PECVD) or plasma enhanced physical vapour deposition (PEPVD), preferably PECVD. The plasma deposition process is typically carried out at a reduced pressure, typically 0.001 to 10 mbar, preferably 0.01 to 1 mbar, for example about 0.7 mbar. The deposition reactions occur in situ on the internal walls of the plasma chamber and/or electrical, and/or on the surface of layers that have already been deposited on the internal walls of the plasma chamber and/or electrical assembly.

Plasma deposition is typically carried out in a reactor that generates plasma which comprises ionized and neutral feed gases/precursors, ions, electrons, atoms, radicals and/or other plasma generated neutral species. A reactor typically comprises a plasma chamber, a vacuum system, and one or more energy sources, although any suitable type of reactor configured to generate plasma may be used. The energy source may include any suitable device configured to convert one or more gases to a plasma. Preferably the energy source comprises a heater, radio frequency (RF) generator, and/or microwave generator.

Plasma deposition results in a unique class of materials which cannot be prepared using other techniques. Plasma deposited materials have a highly disordered structure and are generally highly cross-linked, contain random branching and retain some reactive sites. These chemical and physical distinctions are well known and are described, for example in Plasma Polymer Films, Hynek Biederman, Imperial College Press 2004 and Principles of Plasma Discharges and Materials Processing, 2^{nd} Edition, Michael A. Lieberman, Alan J. Lichtenberg, Wiley 2005.

Typically, in a plasma deposition process a vacuum system is used to pump the plasma chamber down to pressures in the range of 10⁻³ to 10 mbar. One or more gases is typically then injected (at controlled flow rate) into the chamber and an energy source generates a stable gas plasma. One or more precursor compounds is typically then be introduced, as gases and/or vapours, into the plasma phase in the chamber. Alternatively, the precursor compound may be introduced first, with the stable gas plasma generated second. When introduced into the plasma phase, the precursor compounds are typically decomposed (and/or ionized) to generate a range of active species (i.e. radicals) in the plasma that is deposited onto and forms a layers on the exposed surfaces within the plasma chamber.

The exact nature and composition of the material deposited typically depends on one or more of the following conditions (i) the plasma gas selected; (ii) the particular precursor compound(s) used; (iii) the amount of precursor compound(s) [which may be determined by the combination of the pressure of precursor compound(s), the flow rate and the manner of gas injection]; (iv) the ratio of precursor compound(s); (v) the sequence of precursor compound(s); (vi) the plasma pressure; (vii) the plasma drive frequency; (viii) the power pulse and the pulse width timing; (ix) the coating time; (x) the plasma power (including the peak and/or average plasma power); (xi) the chamber electrode arrangement; and/or (xii) the preparation of the incoming assembly.

Typically the plasma drive frequency is 1 kHz to 4 GHz. Typically the plasma power density is 0.001 to 50 W/cm², preferably 0.01 W/cm² to 0.02 W/cm², for example about 0.0175 W/cm². Typically the mass flow rate is 5 to 1000 sccm, preferably 5 to 20 sccm, for example about 10 sccm. Typically the operating pressure is 0.001 to 10 mbar, preferably 0.01 to 1 mbar, for example about 0.7 mbar. Typically the coating time is 10 seconds to >60 minutes, for example 10 seconds to 60 minutes.

Plasma processing can be easily scaled up, by using a larger plasma chamber. However, as a skilled person will appreciate, the preferred conditions will be dependent on the size and geometry of the plasma chamber. Thus, depending on the specific plasma chamber that is being used, it may be beneficial for the skilled person to modify the operating conditions.

### Deposition of the Cover Layer

The present invention involves deposition of a cover layer on the internal walls of an empty plasma chamber by plasma deposition. An empty plasma chamber does not contain any separate, or discrete, objects (such as electrical assemblies). Thus, in contrast to usual plasma deposition methods in which plasma deposition is only carried out when an object to be coated is present within the plasma chamber, the present methods initially involve plasma deposition in the absence of such an object within the plasma chamber.

The internal walls of a plasma chamber typically comprise metallic and non-metallic portions. The internal walls of the plasma chamber are all surfaces within the plasma chamber which will come into contact with plasma during the plasma deposition process, and accordingly upon which material will be deposited during plasma deposition. The internal walls of the plasma chamber thus include permanent elements within the plasma chamber such exposed parts of the gas delivery system or the electrode.

Conformal coatings deposited by plasma deposition, particularly those formed by plasma deposition of fluorine-containing precursors such as hexafluoropropylene (HFP) as described in WO 2013/132250, tend to have good adhesion to metallic surfaces and thus can be difficult to remove from such surfaces. Accordingly, the cover layer of the present invention typically covers at least part of the metallic portions of the internal walls of the plasma chamber, preferably substantially all of the metallic portions (for example, it is particularly preferred that more than 95% of the area of the metallic portions is covered by the cover layer). It is most preferred that all metallic portions of the internal walls of the plasma chamber are covered by the cover layer.

It is generally less important to cover any non-metallic portions of the internal walls of the plasma chamber with the cover layer, since the conformal coatings described above generally adhere less well to such surfaces. Nevertheless, it is preferred that at least part, and more preferably substantially all, of the non-metallic portions of the internal walls of the plasma chamber are covered by the cover layer. For example, it is particularly preferred that more than 95% of the area of the non-metallic portions of the internal walls of the plasma chamber are covered by the cover layer. It is most preferred that all non-metallic portions of the internal walls of the plasma chamber are covered by the cover layer.

The plasma deposition techniques used to prepare the cover layers of the invention will generally deposit the cover layer on all surfaces of the internal walls of the plasma chamber, whether metallic or non-metallic. It is thus particularly preferred that substantially all, for example more than 95% of the area, of the internal walls of the plasma chamber are covered by the cover layer. It is most preferred all of the internal walls of the plasma chamber are covered by the cover layer.

The cover layers of the present invention are hydrocarbon polymer of formula CₘHₙ, which are formed from a precursor mixture that comprises (i) one or more hydrocarbon compounds of formula (A), or (ii) one or more C₁-C₃ alkane, C₂-C₃ alkene or C₂-C3 alkyne compounds. The precursor mixture optionally further comprises a reactive gas (such as NH₃) and/or a non-reactive gas (such as Ar). Typically the precursor mixture consists, or consists essentially, of:
(i) one or more hydrocarbon compounds of formula (A), or (ii) one or more C₁-C₃ alkane, C₂-C₃ alkene or C₂-C₃ alkyne compounds, and
the optional reactive gas(es) and optional non-reactive gas(es).

The hydrocarbon layer of formula CmHn are typically amorphous polymeric hydrocarbons with a linear, branched and/or networked chain structure. Depending on the specific precursor and co-precursor (i.e. reactive gases and/or non-reactive gases) the CmHn layer may contain aromatic rings in the structure. The values of m and n, the density of the polymer and/or presence aromatic rings can be tuned by varying the applied power to generate the plasma and by varying the flow of precursor and/or of the co-precursor. For example, by increasing the power the concentration of aromatic rings can be reduced and the density of the polymer can be increased. By increasing the ratio of the flow rate of the precursors over co-precursor (i.e. reactive gases and/or non-reactive gases) the density of aromatic rings can be increased.

It is a finding of the present invention that hydrocarbon polymers of formula CmHn used to form the cover layers of the present invention achieve a desirable level of adhesion to the internal walls of the plasma chamber. In particular, the cover layer has adequate adhesion to remain attached to the internal walls of the plasma chamber during conformal coating of electrical assemblies, but does not have such high level of adhesion that it cannot be removed easily during subsequent cleaning steps. It is particularly preferred that the cover layer has a level of adhesion to the internal walls of the plasma chamber that enables it to carry, without delaminating, materials deposited at a thickness of 1000 nm to 150 μm during formation of the conformal coatings.

It is preferred that the precursor mixture used to prepare the cover layer contains hydrocarbon compound(s) of formula (A), which have the following structure:

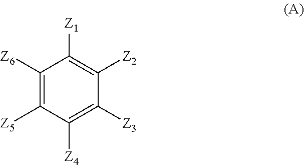

wherein Z₁ represents C₁-C₃ alkyl or C₂-C₃ alkenyl; Z₂ represents hydrogen, C₁-C₃ alkyl or C₂-C₃ alkenyl; Z₃ represents hydrogen, C₁-C₃ alkyl or C₂-C₃ alkenyl; Z₄ represents hydrogen, C₁-C₃ alkyl or C₂-C₃ alkenyl; Z₅ represents hydrogen, C₁-C₃ alkyl or C₂-C₃ alkenyl; and Z₆ represents hydrogen, C₁-C₃ alkyl or C₂-C₃ alkenyl.

Typically, Z₁ represents methyl, ethyl, or vinyl. Typically, Z₂ represents hydrogen, methyl, ethyl, or vinyl. Typically, Z₃ represents hydrogen, methyl, ethyl or vinyl. Typically, Z₄ represents hydrogen, methyl, ethyl or vinyl. Typically, Z₅ represents hydrogen, methyl, ethyl or vinyl, preferably hydrogen. Typically, Z₆ represents hydrogen, methyl, ethyl or vinyl, preferably hydrogen.

Preferably, Z₅ and Z₆ represent hydrogen.

More preferably, Z₁ represents methyl, ethyl or vinyl, Z₂ represents hydrogen, methyl, ethyl or vinyl, Z₃ represents hydrogen, methyl, ethyl or vinyl, Z₄ represents hydrogen, methyl, ethyl or vinyl, Z₅ represents hydrogen and Z₆ represents hydrogen.

It is generally preferred that two of Z₂ to Z₄ represent hydrogen.

Preferred hydrocarbon compounds of formula (A) are 1,4-dimethylbenzene, 1,3-dimethylbenzene, 1,2-dimethylbenzene, toluene, 4-methyl styrene, 3-methyl styrene, 2-methyl styrene, 1,4-divinyl benzene, 1,3-divinyl benzene, 1,2-divinyl benzene, 1,4-ethylvinylbenzene, 1,3-ethylvinylbenze and 1,2-ethylvinylbenzene. 1,4-dimethylbenzene is particularly preferred. Divinyl benzenes are also particularly preferred, and are typically used in the form of a mixture of 1,4-divinyl benzene, 1,3-divinyl benzene and 1,2-divinyl benzene.

The precursor mixture used to prepare the cover layer can alternatively contain one or more C₁-C₃ alkane, C₂-C₃ alkene or C₂-C₃ alkyne compounds. The C₁-C₃ alkane compounds are methane (CH₄), ethane (C₂H₆) and propane (C₃H₈). The C₂-C₃ alkene compounds are ethene (C₂H₄) and propene (C₃H₆). The C₂-C₃ alkyne compounds are ethyne (C₂H₂) and propyne (C₃H₄). Thus, the precursor mixture may contain one or more compounds selected from methane (CH₄), ethane (C₂H₆), propane (C₃H₆), ethene (C₂H₄), propene (C₃H₆), ethyne (C₂H₂) and propyne (C₃H₄). Methane (CH₄), ethane (C₂H₆), propane (OHO, propene (C₃H₆) and ethyne (C₂H₂) are preferred.

The precursor mixture optionally further comprises one or more reactive gases. The or each reactive gas is selected from N₂O, NO₂, NH₃, N₂, CH₄, C₂H₂, C₂H₆, C₃H₆ and C₃H₈. It will be understood that when the precursor mixture already contains CH₄, C₂H₂, C₂H₆, C₃H₆ and/or C₃H₈ as main precursor (ii), these compounds will not be added again as “reactive gases”. These reactive gases are generally involved chemically in the plasma deposition mechanism, and so can be considered to be co-precursors. A skilled person can easily adjust the ratio of reactive gas to other precursor compounds at any applied power density, in order to achieve the desired modification of the resulting layer deposited.

The precursor mixture also optionally further comprises one or more non-reactive gas. The non-reactive gas is He, Ar or Kr, with He and Ar preferred. The non-reactive gas is not involved chemically in the plasma deposition mechanism, but does generally influence the physical properties of the resulting material. For example, addition of He, Ar or Kr will generally increase the density of the resulting layer, and thus its hardness. Addition of He, Ar or Kr also increases cross-linking of the resulting deposited material.

The thickness of the cover layer of the present invention is typically from 5 nm to 1000 nm, preferably from 50 to 500 nm, more preferably from 100 to 300 nm, for example about 200 nm.

The thickness of the cover layer can be easily controlled by a skilled person. Plasma processes deposit a material at a uniform rate for a given set of conditions, and thus the thickness of a layer is proportional to the deposition time. Accordingly, once the rate of deposition has been determined, a layer with a specific thickness can be deposited by controlling the duration of deposition.

The thickness of cover layer may be substantially uniform or may vary from point to point, but is preferably substantially uniform.

Thickness may be measured using techniques known to those skilled in the art, such as a profilometry, reflectometry or spectroscopic ellipsometry.

Deposition of the cover layer may be preceded by a pre-treatment step in which the adhesive properties of the internal walls of the empty plasma chamber are modified, in order to optimise the adhesion between the internal walls and the cover layer. Similarly, deposition of the cover layer may be followed by surface treatment of the cover layer to modify its adhesive properties and optimise adhesion between the cover layer and materials that will be deposited thereon during subsequent formation of conformal coatings.

### Subsequent Deposition of Conformal Coatings

Once the cover layer has been deposited on the internal walls of the plasma chamber, it is possible to introduce the object, such as an electrical assembly, onto which the conformal coating is to be deposited into the plasma chamber. The object is typically an electrical assembly, but may also be any other object upon which it is desirable to coat by plasma deposition, such as a medical device or clothing item. The electrical assembly is preferably a printed circuit board.

When the object, such as an electrical assembly, is inside the plasma chamber, plasma deposition is used to deposit a desired conformal coat onto the object. The desired conformal coating will vary from object to object, and an appropriate conformal coating can be selected by one skilled in the art. A class of conformal coatings that can be particularly favourably used are the multilayer coatings described in WO 2013/132250, WO 2014/155099 and WO 2016/198870, the content of which are herein incorporated by reference.

During the formation of the conformal coating on the object, the materials generated by the plasma deposition process will also be deposited onto the cover layer. The materials generated by the plasma deposition process will also be deposited on any areas of the internal wall of the plasma chamber which are not covered by the cover layer, and so it is generally preferred that internal walls of the plasma chamber are completely covered by the cover layer, as discussed above.

Conformal coatings which are prepared by initial plasma deposition of fluorohydrocarbons such as CF₄, C₂F₄, C₂F₆, C₃F₆, C₃F₈ or C₄F₈ as precursors are particularly suited for use with the cover layers of the present invention. That is because the resulting fluorine-containing coatings adhere very well to metallic surfaces. This property is highly desirable in a conformal coating for an object with metal areas such as an electrical assembly, but is undesirable for the metallic portions of the internal walls of the plasma chamber (since cleaning will be very difficult). The cover layers of the present invention prevent the fluorine-containing coatings from being deposited directly on to the internal walls of the plasma chamber, and thus overcome the problem of cleaning such fluorine-containing coatings from metallic surfaces.

It is thus preferred according to the present invention that the conformal coating is prepared by initially depositing by plasma deposition a precursor mixture comprising a fluorohydrocarbon such as CF₄, C₂F₄, C₂F₆, C₃F₆, C₃F₈ or C₄F₈.

Once the conformal coating has been deposited on the object, the object with a conformal coating is removed from the plasma chamber.

The overall conformal coating process is thus as follows:

(a) an object, typically an electrical assembly, is introduced into the empty plasma chamber,

(b) a conformal coating is deposited onto the object, typically an electrical assembly, by plasma deposition to provide an object, typically an electrical assembly, with a conformal coating, and

(c) the object, typically an electrical assembly, with a conformal coating is removed from the plasma chamber.

The coating procedure [i.e. steps (a) to (c)]can then be repeated as many time as desired on further an objects. Each time the coating procedure is repeated, the amount of material deposited on the cover layer increases.

### Cleaning the Internal Walls of the Plasma Chamber

When repeated cycles of conformal coating deposition are carried out on multiple objects, there will be a build-up of material on the cover layer. The materials deposited on the cover layer may start to interfere physically and/or chemically with the plasma deposition process if present in significant amounts. The efficiency of the conformal coating process may also be adversely affected. It is thus necessary to remove the cover layer and materials deposited thereon regularly, thereby providing a clean plasma chamber. A skilled person will be able to assess using routine examination and analytic techniques when it is necessary to conduct the cleaning step.

The cleaning step uses any suitable technique to detach the cover layer from the inner walls of the plasma chamber, and thereby remove the cover layer and materials deposited thereon from the plasma chamber. Physical cleaning techniques, such as mechanical impact, scratching, rubbing or suction, are preferred. That is because these techniques can efficiently remove the cover layer and materials deposited thereon, due to the properties of the cover layer. Suction is particularly preferred. Alternatively, routine plasma cleaning or etching can be used to remove the cover layer and materials deposited thereon from the plasma chamber.

Once the cover layer and materials deposited thereon have been removed, and the walls of the plasma chamber are clean, it will generally be desirable to add a new cover layer. The plasma chamber will then be ready for further conformal coating of electrical assemblies.

### The Electrical Assembly

An electrical assembly used in the present invention typically comprises a substrate comprising an insulating material, a plurality of conductive tracks present on at least one surface of the substrate, and at least one electrical component connected to at least one conductive track. The conformal coating preferably covers the plurality of conductive tracks, the at least one electrical component and the surface of the substrate on which the plurality of conductive tracks and the at least one electrical component are located. Alternatively, the coating may cover one or more electrical components, typically expensive electrical components in the PCB, whilst other parts of the electrical assembly are uncovered.

A conductive track typically comprises any suitable electrically conductive material. Preferably, a conductive track comprises gold, tungsten, copper, silver, aluminium, doped regions of semi-conductor substrates, conductive polymers and/or conductive inks. More preferably, a conductive track comprises gold, tungsten, copper, silver or aluminium.

Suitable shapes and configurations for the conductive tracks can be selected by a person skilled in the art for the particular assembly in question. Typically, a conductive track is attached to the surface of the substrate along its entire length. Alternatively, a conductive track may be attached to the substrate at two or more points. For example, a conductive track may be a wire attached to the substrate at two or more points, but not along its entire length.

A conductive track is typically formed on a substrate using any suitable method known to those skilled in the art. In a preferred method, conductive tracks are formed on a substrate using a “subtractive” technique. Typically in this method, a layer of metal (e.g., copper foil, aluminium foil, etc.) is bonded to a surface of the substrate and then the unwanted portions of the metal layer are removed, leaving the desired conductive tracks. The unwanted portions of the metal layer are typically removed from the substrate by chemical etching or photo-etching or milling. In an alternative preferred method, conductive tracks are formed on the substrate using an “additive” technique such as, for example, electroplating, deposition using a reverse mask, and/or any geometrically controlled deposition process. Alternatively, the substrate may be a silicon die or wafer, which typically has doped regions as the conductive tracks.

The substrate typically comprises any suitable insulating material that prevents the substrate from shorting the circuit of electrical assembly. The substrate preferably comprises an epoxy laminate material, a synthetic resin bonded paper, an epoxy resin bonded glass fabric (ERBGH), a composite epoxy material (CEM), PTFE (Teflon), or other polymer materials, phenolic cotton paper, silicon, glass, ceramic, paper, cardboard, natural and/or synthetic wood based materials, and/or other suitable textiles. The substrate optionally further comprises a flame retardant material, typically Flame Retardant 2 (FR-2) and/or Flame Retardant 4 (FR-4). The substrate may comprise a single layer of an insulating material or multiple layers of the same or different insulating materials. The substrate may be the board of a printed circuit board (PCB) made of any one of the materials listed above.

An electrical component may be any suitable circuit element of an electrical assembly. Preferably, an electrical component is a resistor, capacitor, transistor, diode, amplifier, relay, transformer, battery, fuse, integrated circuit, switch, LED, LED display, Piezo element, optoelectronic component, antenna or oscillator. Any suitable number and/or combination of electrical components may be connected to the electrical assembly.

The electrical component is preferably connected to an electrically conductive track via a bond. The bond is preferably a solder joint, a weld joint, a wire-bond joint, a conductive adhesive joint, a crimp connection, or a press-fit joint. Suitable soldering, welding, wire-bonding, conductive-adhesive and press-fit techniques are known to those skilled in the art, for forming the bond. More preferably the bond is a solder joint, a weld joint or a wire-bond joint, with a solder joint most preferred.

### Definitions

As used herein, the term C₁-C₆ alkyl embraces a linear or branched hydrocarbon groups having 1 to 6, preferably 1 to 3 carbon atoms. Examples include methyl, ethyl, n-propyl and i-propyl, butyl, pentyl and hexyl. As used herein, the term C₁-C₃ alkyl embraces a linear or branched hydrocarbon group having 1 to 3, preferably 1 to 2 carbon atoms. Examples include methyl, ethyl, n-propyl and i-propyl.

As used herein, the term C₂-C₆ alkenyl embraces a linear or branched hydrocarbon groups having 2 or 6 carbon atoms, preferably 2 to 4 carbon atoms, and a carbon-carbon double bond. Preferred examples include vinyl and allyl. As used herein, the term C₂-C₃ alkenyl embraces a linear or branched hydrocarbon group having 2 or 3 carbon atoms and a carbon-carbon double bond. A preferred example is vinyl.

As used herein, the term C₁-C₆ alkoxy group is a said alkyl group which is attached to an oxygen atom. Preferred examples include methoxy, ethoxy, propoxy, isopropoxy, butoxy, isobutoxy, tert-butoxy, pentoxy and hexoxy.

### DETAILED DESCRIPTION OF THE FIGURES

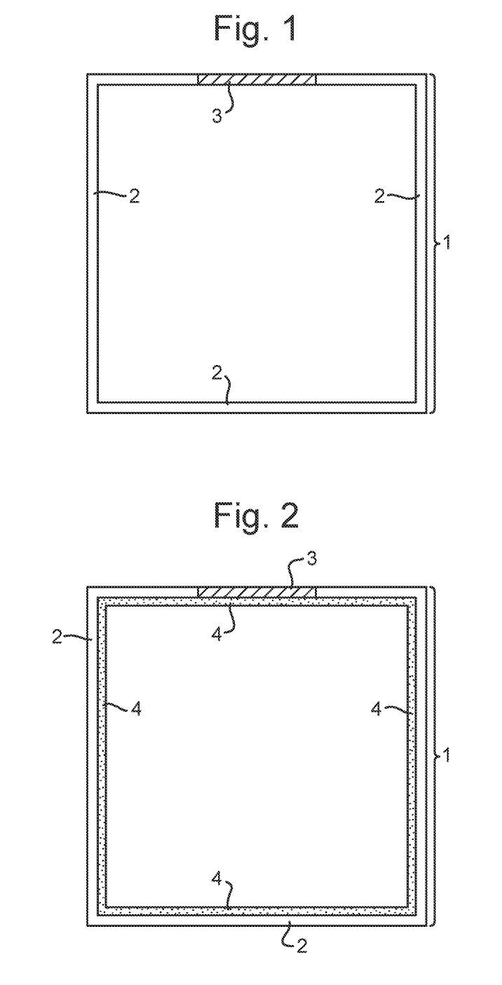

Aspects of the invention will now be described with reference to the embodiment shown in FIGS. 1 to 3, in which like reference numerals refer to the same or similar components.

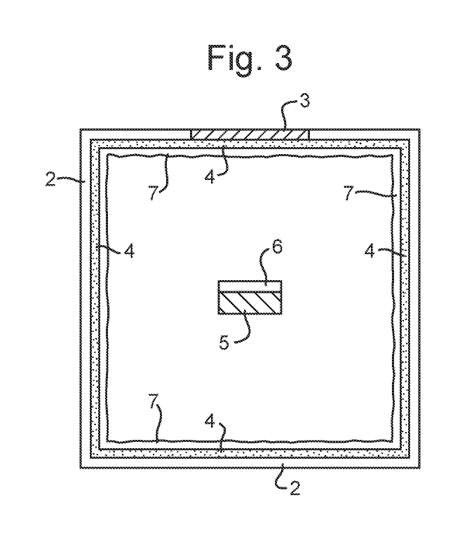

FIG. 1 shows an empty plasma chamber 1. The internal walls 2 and 3 of the empty plasma chamber 1 are clean and uncoated. The internal walls of the plasma chamber have metallic portions 2 and non-metallic portions 3. FIG. 1 represents both (a) an empty plasma chamber prior to addition of a cover layer as depicted in FIG. 2, and (b) an empty plasma chamber prepared following cleaning and removal of layers 6 and 7 depicted in FIG. 3.

FIG. 2 shows an empty plasma chamber 1. The internal walls 2 and 3 of the empty plasma chamber 1 are coated with cover layer 4. Cover layer 4 covers both metallic portions 2 and non-metallic portions 3 of the internal walls of the empty plasma chamber 1. Cover layer 4 of the empty plasma chamber 1 is prepared by plasma deposition of a precursor mixture comprising (i) one or more hydrocarbon compounds of formula (A), or (ii) one or more C₁-C₃ alkane, C₂-C₃ alkene or C₂-C₃ alkyne compounds.

FIG. 3 shows a plasma chamber which is not empty but contains an electrical assembly 5. The electrical assembly 5 has a conformal coating 6 which has been deposited by plasma deposition. Formation of conformal coating 6 has also resulted in deposition of material 7 on top of cover layer 4.

### EXAMPLES

Aspects of the invention will now be described with reference to the following examples.

### Example 1

A cover layer is first deposited on the internal surfaces of an empty plasma chamber (i.e. a plasma chamber that does not contain an electrical assembly) by plasma deposition of 1,4-dimethyl benzene. The resulting cover layer of formula CₘHₙ is 200 nm thick. The capped plasma chamber is then used to deposit conformal coatings on electrical assemblies using the techniques described in WO 2013/132250.

During deposition of the conformal coatings onto the electrical assemblies, materials are deposited also onto the cover layer. Once preparation of the electrical assemblies with conformal coatings is complete, the internal surfaces of the plasma chamber are cleaned using vacuum suction. The vacuum suction removes both the cover layer and the materials deposited on it during deposition of the conformal coatings, leaving a clean plasma chamber with uncoated internal surfaces.

1. A plasma deposition method in which a cover layer is deposited onto the internal walls of an empty plasma chamber by plasma deposition of a precursor mixture comprising (i) one or more hydrocarbon compounds of formula (A), or (ii) one or more C₁-C₃ alkane, C₂-C₃ alkene or C₂-C₃ alkyne compounds: 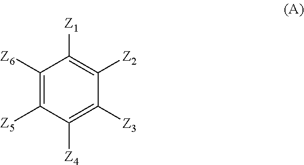
wherein:
Z₁ represents C₁-C₃ alkyl or C₂-C₃ alkenyl;
Z₂ represents hydrogen, C₁-C₃ alkyl or C₂-C₃ alkenyl;
Z₃ represents hydrogen, C₁-C₃ alkyl or C₂-C₃ alkenyl;
Z₄ represents hydrogen, C₁-C₃ alkyl or C₂-C₃ alkenyl;
Z₅ represents hydrogen, C₁-C₃ alkyl or C₂-C₃ alkenyl; and
Z₆ represents hydrogen, C₁-C₃ alkyl or C₂-C₃ alkenyl.

2. The method according to claim 1, wherein the plasma deposition is plasma enhanced chemical vapour deposition (PECVD).

3. The method according to claim 1 or 2, wherein the plasma deposition occurs at a pressure of 0.001 to 10 mbar.

4. The method according to any one of the preceding claims, wherein the or each hydrocarbon compound of formula (A) is selected from 1,4-dimethylbenzene, 1,3-dimethylbenzene, 1,2-dimethylbenzene, toluene, 4-methyl styrene, 3-methyl styrene, 2-methyl styrene, 1,4-divinyl benzene, 1,3-divinyl benzene, 1,2-divinyl benzene, 1,4-ethylvinylbenzene, 1,3 -ethylvinylbenzene and 1,2-ethylvinylbenzene.

5. The method according to claim 4, wherein the hydrocarbon compound of formula (A) is 1,4-dimethylbenzene.

6. The method according to claim 4, wherein the one or more hydrocarbon compounds of formula (A) is a mixture of 1,4-divinyl benzene, 1,3-divinyl benzene and 1,2-divinyl benzene.

7. The method according to any one of the preceding claims, wherein the precursor mixture further comprises one or more reactive gases selected from N₂O, NO₂, NH₃, N₂, CH₄, C₂H₂, C₂H₆, C₃H₆ and C₃H_{8.}

8. The method according to any one of the preceding claims, wherein the precursor mixture further comprises one or more non-reactive gases selected from He, Ar and Kr.

9. The method according to any one of the preceding claims, wherein the thickness of the cover layer is from 5 nm to 1000 nm.

10. The method according to any one of the preceding claims, wherein deposition of the cover layer is preceded by pre-treatment step in which the adhesive properties of the internal walls of the empty plasma chamber are modified.

11. The method according to any one of the preceding claims, wherein deposition of the cover layer is followed by surface treatment of the cover layer to modify its adhesive properties.

12. The method according to any one of the preceding claims, wherein following deposition of the cover layer:
(a) an object is introduced into the empty plasma chamber,
(b) a conformal coating is deposited onto the object by plasma deposition to provide an object with a conformal coating, and
(c) the object with a conformal coating is removed from the plasma chamber.

13. The method according to claim 12, wherein steps (a) to (c) are repeated one or more times.

14. The method according to claim 12 or 13, wherein the object is an electrical assembly.

15. The method according to claim 14, wherein the electrical assembly is a printed circuit board.

16. The method according to any one of claims 12 to 15, wherein, following removal of the object with a conformal coating from the plasma chamber, the cover layer and any materials deposited thereon during deposition of the conformal coating are removed from the internal walls of the plasma chamber.

17. The method according to claim 17, wherein the cover layer and any materials deposited thereon during deposition of the conformal coating are removed by a physical cleaning technique.
